(19) United States
(12) Patent Application Publication
(10) Pub. No.: US 2014/0056443 A1
(43) Pub. Date: Feb. 27, 2014

(54) Audio Amplifier for Portable Devices

(71) Applicant: Amazing Creative Co. Ltd., Kowloon (HK)

(72) Inventors: Lau Chi Yui, Kowloon (HK); Leung Wing Yan, Kowloon (HK)

(21) Appl. No.: 13/903,649

(22) Filed: May 28, 2013

(30) Foreign Application Priority Data
May 29, 2012 (CN) 201220245946.0

(51) Int. Cl. H03F 3/181

(52) U.S. Cl. CPC H03F 3/181
USPC 381/120

(57) ABSTRACT

An audio amplifier for portable devices is provided, which includes a hollow or a solid shell body and an inner container receiving in the shell body, a large opening for sound transmission is defined on the front of the shell body, and a groove is disposed on the top of the shell body, a sound absorbing aperture is defined at the bottom of the groove, the inner container comprises a curve-shaped pipeline which extends inwards from the sound absorbing aperture to the shell body until arriving the large opening for sound transmission, and the width of the curve-shaped pipeline is increased gradually as the curve-shaped pipeline extends inwards.

### FIELD OF THE INVENTION

The present invention relates to audio amplifiers, more particularly, to an audio amplifier for portable devices.

### BACKGROUND OF THE INVENTION

With the rapid development of electronic communication technology, portable devices such as mobile phones and palm computers are integrated with lots of functions including game player, music player and recorder other than the typical fundamental functions. However, these portable devices are played via headsets or small inbuilt loudspeakers, wherein, the headsets can just meet the need of personal enjoyment, the power and the sound volume of the inbuilt loudspeakers are low, and the tone quality of the inbuilt loudspeakers are poor. Sometimes, the inbuilt loudspeakers may generate noises when they are turned up to their maximum volumes. The sound volume of a portable device can be intensified by users merely via making an external loudspeaking apparatus connected to the portable device, which has undoubtedly increased the cost and the electricity consumption of the electrical device.

### SUMMARY OF THE INVENTION

Aiming at aforementioned drawbacks in the prior art, the objective of the present invention is to provide an audio amplifier for portable devices which is provided with a handsome appearance and can achieve sound amplifying effect via the use of resonation without any electrical sources.

The technical proposal of the present invention is implemented by providing an audio amplifier for portable devices which comprises a hollow or a solid shell body and an inner container receiving in the shell body, a large opening for sound transmission is defined on the front of the shell body, and a groove is disposed on the top of the shell body, a sound absorbing aperture is defined at the bottom of the groove, the inner container includes a curve-shaped pipeline which extends from the sound absorbing aperture inwards to the shell body until arriving the large opening for sound transmission, and the width of the curve-shaped pipeline is increased gradually as the curve-shaped pipeline extends inwards.

In the audio amplifier for portable devices of the present invention, the groove is used for receiving a portable device, and the location of the sound absorbing aperture defined at the bottom of the groove is opposite to the location of a loudspeaker of the portable device.

In the audio amplifier for portable devices of the present invention, the shape of the groove is matched with the appearance and the dimension of the portable device received in the groove.

The shell body may have various shapes comprising different terrestrial and marine animal type models or cartoon character type models, portrait models, monster models, skull models, duck-type models, square types, type models of different shapes and materials, photo frame-type models and fruit-based models.

The principle for audio amplifying in the present invention is illustrated as follows. The sound generated by the portable device located in the groove enters and propagates in the curve-shaped pipeline via the sound absorbing aperture. On one hand, it can avoid the sound from spreading. On the other hand, the sound can be reflected and resonated in the pipeline, which leads to overlapping the amplitudes of the sound waves. The sound waves may transmit towards the pipeline that becomes thicker gradually while the amplitude is overlapped obviously. Thus, when the sound is transmitted out from the large opening for sound transmission, the volume of the sound has been increased, the quality of the sound has been improved and the exquisite original sound has been maintained synchronously, which makes an optimized audio effect of the sound possible.

When implementing the present invention, the following advantageous effects can be achieved: it is unnecessary to add any audio amplifying circuits and loudspeakers to increase the volume and improve the tone quality of a portable device. Besides, the audio amplifier for portable devices of the present invention has low cost, and the shell body of which can be designed changeable according to the demand both for the appearance and the performance.

### BRIEF DESCRIPTION OF THE DRAWINGS

The present invention will be further described with reference to the accompanying drawings and embodiments in the following, in the accompanying drawings:

FIG. 1 is a front schematic view of an audio amplifier for portable devices in accordance with an embodiment of the present invention;

FIG. 2 is a lateral view of an audio amplifier for portable devices in accordance with an embodiment of the present invention;

FIG. 3 illustrates a plurality of structural schematic views of a shell body in accordance with an embodiment of the present invention in the form of back view (a), plan view (b), left lateral view (c), right lateral view (c) and front view (d) respectively;

FIG. 4 illustrates a plurality of structural schematic views of an inner container for audio amplifying in accordance with an embodiment of the present invention in the form of back view (a), plan view (b), left lateral view (c), right lateral view (c) and front view (d) respectively;

FIG. 5 shows the principle of audio amplifying in accordance with an embodiment of the present invention.

### DETAILED DESCRIPTION OF THE PREFERRED EMBODIMENT

To make the technical feature, objective and effect of the present invention be understood more clearly, now the specific implementation of the present invention is described in detail with reference to the accompanying drawings and embodiments.

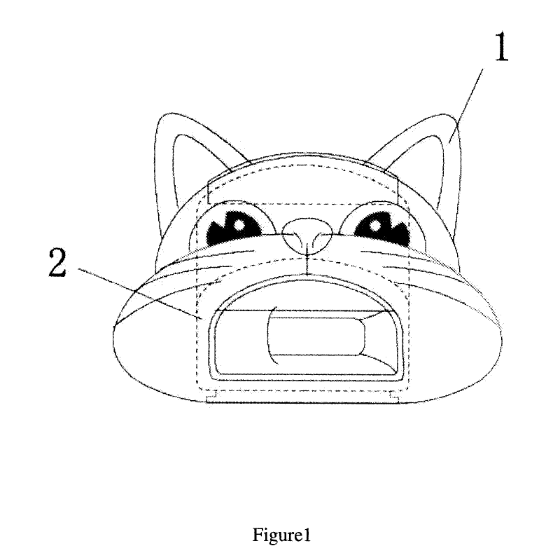

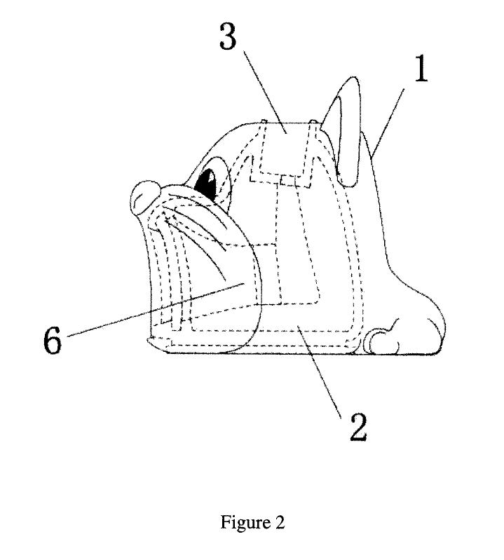

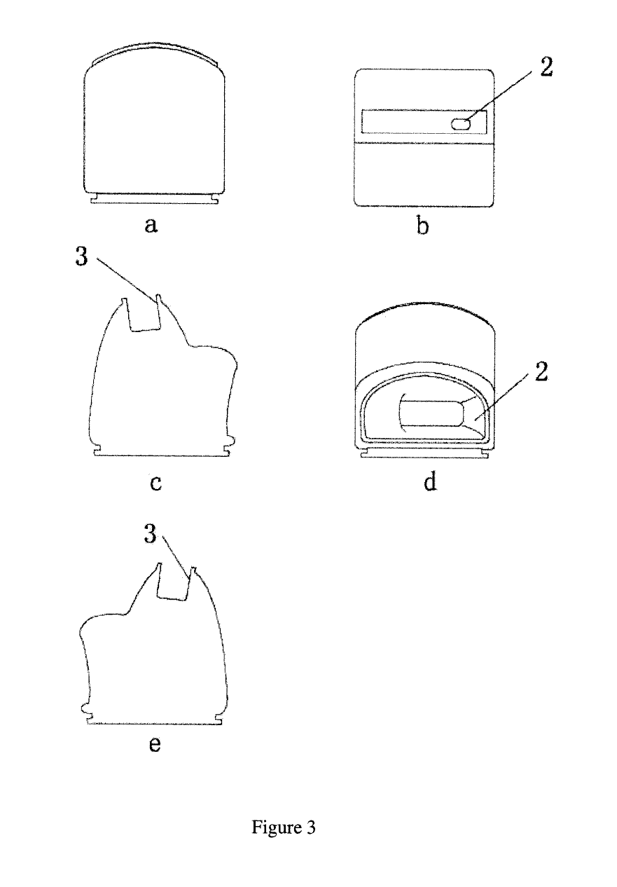

The present invention has disclosed a kind of audio amplifier for portable devices, which comprises a hollow or a solid shell body 1 and an inner container 2 receiving in the shell body 1, the appearance of the shell body 1 is various, which is not limited to animals and cartoon characters. As shown in FIG. 1, FIG. 2 and FIG. 3, the shape of the shell body 1 is a head of a cat, the pedestal of the audio amplifier is horizontally orientated to ensure the audio amplifier to be placed stably, the overhead view of the shell body 1 appears as a square with four smoothed angles, wherein, a groove 3 is disposed in the front of the cat ear on the top of the shell body 1, and a sound absorbing aperture 4 is defined on the right side of the bottom of the groove 3, the open mouth of the cat disposed on the surface of the shell body 1 is equal to the large opening for sound transmission 5 in the embodiment of the present invention. The shape of the groove 3 matches with the portable device 7, and the location of the sound absorbing aperture 4 faces the location of the loudspeaker of the portable device 7, the aforementioned structure of the shell body 1 is used for sustaining the portable device 7 and absorbing the sound generated by the portable device 7 as much as possible.

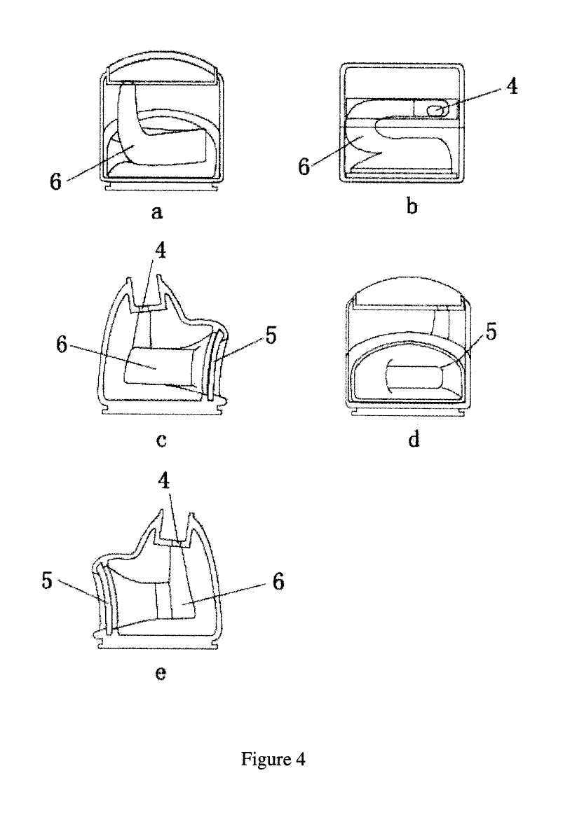

As shown in FIG. 4, the inner container 2 includes a curve-shaped pipeline 6 in the embodiment of the present invention, and the curve-shaped pipeline 6 extends inwards from the sound absorbing aperture 4 to the shell body 1 until reaching the large opening for sound transmission 5, the curve-shaped pipeline 6 becomes wider and wider as it extends inwards. Firstly, the curve-shaped pipeline 6 extends downwards to some extent and bends to the left horizontally, then, the curve-shaped pipeline 6 continues to extend downwards to some extent and bends to the right, finally, the curve-shaped pipeline 6 arrives the large opening for sound transmission 5. As the curve-shaped pipeline 6 extends inwards to the shell body 1, the width of the cross section of the curve-shaped pipeline 6 is increased gradually, and the curve-shaped pipeline 6 extends to the large opening for sound transmission 5 disposing on the surface of the shell body 1 finally. The vertical view of the inner container 2 is an irregular S-shape, and the inner container 2 is becoming wider gradually, the head of the inner container 2 is designed to be the sound absorbing aperture 4, and the tail of the inner container 2 is designed to be the large opening for sound transmission 5. The left lateral view of the inner container 2 looks like an L-shape, and the thickness of the cross section of the L-shape is increased gradually, the right lateral view of the inner container 2 looks like a reversed L-shape, and the thickness of the cross section of the reversed L-shape is increased gradually. The large opening for sound transmission 5 is trumpet-shaped.

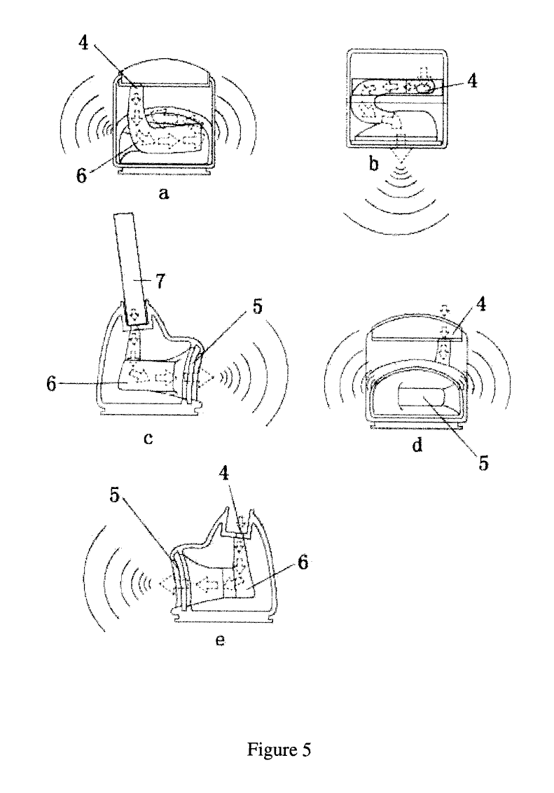

As shown in FIG. 5, the principle of audio amplifying in the embodiment of the present invention is illustrated, the directions indicated by the arrows shown in FIG. 5a, FIG. 5b, FIG. 5c, FIG. 5d and FIG. 5e are the propagation directions of sound waves. The sound generated by the portable device 7 enters the inner container 2 via the sound absorbing aperture 4 and propagates in the curve-shaped pipeline 6. On one hand, the diffusion of the sound can be reduced during its propagation, on the other hand, the sound is reverberated by the inner wall of the curve-shaped pipeline 6, which leads to the resonation, so that the amplitudes of sound waves are overlapped. The resonation is intensified and far more obvious due to the design of the structure of the curve-shaped pipeline 6, that is, the curve-shaped pipeline 6 is designed to be thicker and thicker gradually, which makes the effect of multiple amplifications for sound possible. Thus, when the sound is transmitted out from the large opening for sound transmission 5, the volume of the sound is increased and the exquisite original sound is maintained synchronously, which makes an optimized audio effect of the sound possible.

While the embodiments of the present invention are described with reference to the accompanying drawings above, the present invention is not limited to the above-mentioned specific implementations. In fact, the above-mentioned specific implementations are intended to be exemplary not to be limiting. In the inspiration of the present invention, those ordinary skills in the art can also make many modifications without breaking away from the subject of the present invention and the protection scope of the claims. All these modifications belong to the protection of the present invention.

1. An audio amplifier for portable devices, wherein, comprising: a hollow or a solid shell body and an inner container receiving in the shell body, a large opening for sound transmission is defined on the front of the shell body, and a groove is disposed on the top of the shell body, a sound absorbing aperture is defined at the bottom of the groove, the inner container includes a curve-shaped pipeline which extends inwards from the sound absorbing aperture to the shell body until arriving the large opening for sound transmission, and the width of the curve-shaped pipeline is increased gradually as the curve-shaped pipeline extends inwards.

2. The audio amplifier for portable devices according to claim 1, wherein, the groove is used for receiving a portable device, and the location of the sound absorbing aperture defined at the bottom of the groove is opposite to the location of a loudspeaker of the portable device.

3. The audio amplifier for portable devices according to claim 1, wherein, the shape of the groove matches with the appearance and the dimension of the portable device received in the groove.
